(19) United States
(12) Patent Application Publication
(10) Pub. No.: US 2009/0057837 A1
(43) Pub. Date: Mar. 5, 2009

(54) WAFER WITH EDGE NOTCHES ENCODING WAFER IDENTIFICATION DESCRIPTOR

(76) Inventors: LESLIE MARSHALL, Austin, TX (US); Gerald L. Goff, Austin, TX (US)

Correspondence Address: WILLIAMS, MORGAN & AMERSON, 10333 RICHMOND, SUITE 1100, HOUSTON, TX, 77042, US

(21) Appl. No.: 11/849,775

(22) Filed: Sep. 4, 2007

(51) Int. Cl. H01L 29/06; G01B 11/00

(52) U.S. Cl. 257/618; 356/601; 257/E23.179

(57) ABSTRACT

An apparatus includes a semiconductor wafer having a surface terminating in an edge. A plurality of notches is defined along the edge. The plurality of notches encodes a wafer identification descriptor for the wafer. A system for identifying wafers includes a wafer sorter. The wafer sorter is adapted to scan at least a portion of a wafer including the plurality of notches and decode the scan of the plurality of notches to generate a wafer identification descriptor for the wafer.

### CROSS-REFERENCE TO RELATED APPLICATIONS

Not applicable.

### BACKGROUND OF THE INVENTION

This present subject matter relates generally to the field of semiconductor device manufacturing and, more particularly, to a method and apparatus for determining wafer identity using edge notches encoding a wafer identification descriptor.

During the manufacture of semiconductor devices, semiconductor wafers, each including a plurality of individual die, are subjected to a number of processing steps. Typically, wafers are grouped into lots that are processed together. Each lot may contain, for example, 25 individual wafers. As a lot of wafers progresses through the processing line, the wafers are typically housed in a carrier.

FIG. 1 illustrates a typical semiconductor wafer 10. The wafer 10 includes an orientation notch 20 useful as a reference point for orienting the wafer 10. In some instances, a wafer includes a flat edge region referred to as a wafer flat 25 (i.e., shown in phantom) in lieu of a notch 20. Some of the processes performed on the wafer 10 (e.g., photolithography) are highly sensitive to wafer orientation. Typically, prior to performing an orientation-sensitive process the wafer is rotated until the notch 20 or flat 25 is located and placed in a predetermined position. For identification purposes, a unique wafer identification code 30 is scribed on the wafer 10 beneath the notch 20 or flat 25 using a laser scribing process where small dots are burned into the surface to construct the characters or symbols of the code. Exemplary wafer identification codes 30 may include alphanumeric identifiers or bar code identifiers (e.g., 1 or 2 dimensional codes). During the production process, process history and metrology information is stored in a database for each of the wafers 10 indexed by its respective wafer identification code 30.

One issue associated with the wafer identification code 30 is that it tends to become harder to read as the wafer 10 progresses through the manufacturing process. Wafers 10 are subjected to a wide variety of processes, such as chemical and physical etching, polishing, annealing, that have a tendency to degrade the wafer identification code 30. The wafer processing tends to cause a darkening of the wafer surface, resulting in poor optical contrast between the wafer scribe and the wafer surface. In some cases the degradation in the wafer identification code 30 is sufficiently severe that it can no longer be read. One technique for countering the degradation is the use of self correcting coding techniques, such as two dimensional bar coding, that encode redundant information in horizontal and vertical patterns. If a portion of the pattern is obscured, the missing information may sometimes be recreated from the redundant information. Even with such information redundancy, some wafer identification codes 30 may still degrade to the point where they are unreadable.

This section of this document is intended to introduce various aspects of art that may be related to various aspects of the disclosed subject matter described and/or claimed below. This section provides background information to facilitate a better understanding of the various aspects of the disclosed subject matter. It should be understood that the statements in this section of this document are to be read in this light, and not as admissions of prior art. The disclosed subject matter is directed to overcoming, or at least reducing the effects of, one or more of the problems set forth above.

### BRIEF SUMMARY OF THE INVENTION

The following presents a simplified summary of the disclosed subject matter in order to provide a basic understanding of some aspects of the disclosed subject matter. This summary is not an exhaustive overview of the disclosed subject matter. It is not intended to identify key or critical elements of the disclosed subject matter or to delineate the scope of the disclosed subject matter. Its sole purpose is to present some concepts in a simplified form as a prelude to the more detailed description that is discussed later.

One aspect of the disclosed subject matter is seen in an apparatus including a semiconductor wafer having a surface terminating in an edge. A plurality of notches is defined along the edge. The plurality of notches encodes a wafer identification descriptor for the wafer.

Another aspect of the disclosed subject matter is seen a system for identifying wafers. Each wafer includes a surface terminating in an edge and a plurality of notches defined along the edge. The system includes a scanner adapted to scan at least a portion of a wafer including the plurality of notches and decode the scan of the plurality of notches to generate a wafer identification descriptor for the wafer.

### BRIEF DESCRIPTION OF THE SEVERAL VIEWS OF THE DRAWINGS

The disclosed subject matter will hereafter be described with reference to the accompanying drawings, wherein like reference numerals denote like elements, and:

FIG. 1 is a simplified diagram of a prior art semiconductor wafer including an orientation notch and a wafer identification code;

FIGS. 2 and 3 are a simplified diagrams of semiconductor wafers having notched edge scribes in accordance with one illustrative embodiment of the subject matter;

FIG. 4 is a simplified diagram of a system used to identify the wafer of FIG. 2 or 3; and

FIG. 5 depicts a portion of the wafer of FIG. 3 to illustrate how additional wafer identification marks may be added to assign a new identification code to a reclaimed wafer.

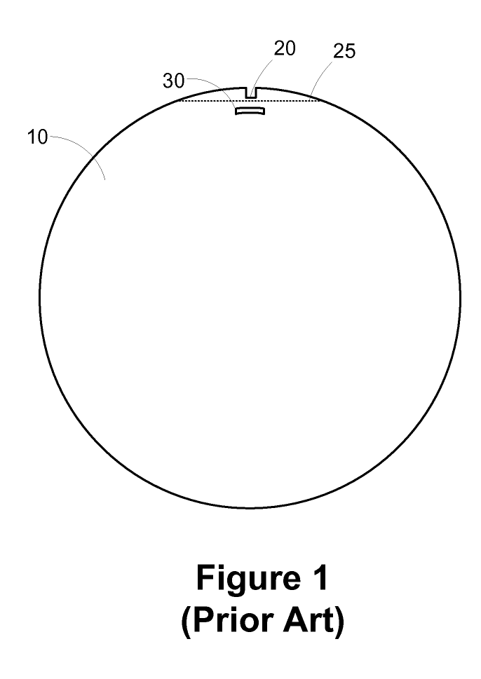

While the disclosed subject matter is susceptible to various modifications and alternative forms, specific embodiments thereof have been shown by way of example in the drawings and are herein described in detail. It should be understood, however, that the description herein of specific embodiments is not intended to limit the disclosed subject matter to the particular forms disclosed, but on the contrary, the intention is to cover all modifications, equivalents, and alternatives falling within the spirit and scope of the disclosed subject matter as defined by the appended claims.

### DETAILED DESCRIPTION OF THE INVENTION

One or more specific embodiments of the disclosed subject matter will be described below. It is specifically intended that the disclosed subject matter not be limited to the embodiments and illustrations contained herein, but include modified forms of those embodiments including portions of the embodiments and combinations of elements of different embodiments as come within the scope of the following claims. It should be appreciated that in the development of any such actual implementation, as in any engineering or design project, numerous implementation-specific decisions must be made to achieve the developers' specific goals, such as compliance with system-related and business related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure. Nothing in this application is considered critical or essential to the disclosed subject matter unless explicitly indicated as being “critical” or “essential.”

The disclosed subject matter will now be described with reference to the attached figures. Various structures, systems and devices are schematically depicted in the drawings for purposes of explanation only and so as to not obscure the disclosed subject matter with details that are well known to those skilled in the art. Nevertheless, the attached drawings are included to describe and explain illustrative examples of the disclosed subject matter. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

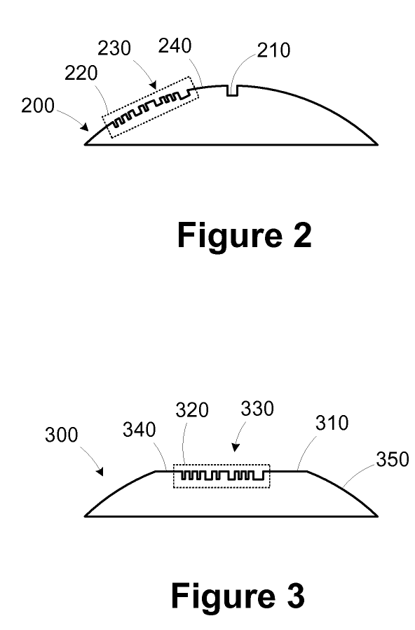

Referring now to the drawings wherein like reference numbers correspond to similar components throughout the several views and, specifically, referring to FIG. 2, the disclosed subject matter shall be described in the context of a semiconductor wafer 200 identified in accordance with one illustrative embodiment of the present invention. The wafer 200 includes an orientation notch 210 and a wafer identification descriptor 220 defined by a plurality of identification notches 230 disposed on an edge 240 of the wafer 200. The pattern defined by the identification notches 230 encodes the wafer identification descriptor 220 to uniquely identify the wafer 200. For purposes of illustration, the size and depth of the identification notches 230 are exaggerated. In an actual embodiment, the size of the identification notches 230 may be significantly smaller in size relative to the size of the orientation notch 210.

The particular notch structure used to define the wafer identification descriptors 220 may vary depending on the particular embodiment. Generally, by varying the width of the identification notches 230 and/or the spacing between the identification notches 230, a code may be defined.

Turning to FIG. 3, a semiconductor wafer 300 is shown that includes a wafer flat 310. A wafer identification descriptor 320 is defined by identification notches 330 are disposed along an edge 340 defined by the wafer flat 310. Although, the identification notches 330 are illustrated as being disposed along the wafer flat 310, it is also contemplated that the identification notches 330 may be disposed on a curved edge 350 of the wafer 300, similar to the embodiment illustrated in FIG. 2. The particular location of the identification notches 330 may vary depending on the nature of the system used to read the wafer identification code. For example, if the identification notches 330 were disposed on the curved edge 350 of the wafer 300, the same system could be used to read wafers 200, 300 with orientation notches 210 or wafer flats 310.

It is also contemplated that the wafer 200, 300 be provided without an orientation notch 210 or flat 310. The identification notches 230 may be provided with defined start and stop patterns (e.g., defined by the outermost notches 230) that may be used to align the wafer 200 and read the wafer identification descriptor 220 in a single action, thereby reducing cycle time.

Various pieces of equipment in a fabrication facility may be equipped with hardware for reading the wafer identification descriptors 320. This equipment may include wafer sorters, process tools, metrology tools, transport devices, etc.

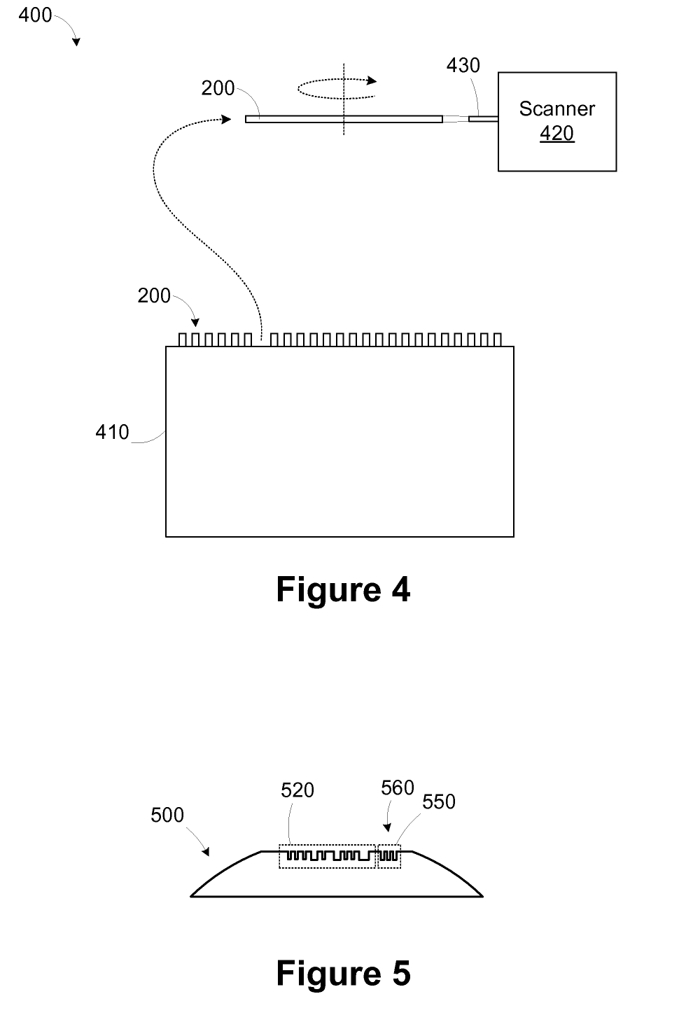

FIG. 4 is a simplified diagram of a wafer sorting system 400 used to identify the wafer 200 (i.e., or the wafer 300). A wafer carrier 410 holds a lot of wafers 200. Handling equipment (not shown), such as an arm may be provided for extracting a wafer 200 from the carrier 410 and rotating the wafer 200 to a known position (e.g., using the notch 210, flat 310, or the identification notches 230). Suitable handling equipment, such as a robotic arm and a rotating platen are known to those of ordinary skill in the art. A scanner 420 having an optical sensor 430 reads the wafer identification descriptors 220 defined by the identification notches 230. In some embodiments, the scanner 420 may read an entire wafer identification descriptor 220 at once, while in other embodiments, the scanner 420 may read each of the identification notches 230 in series to determine the pattern in width and/or spacing of the identification notches 230. In such a serial approach, the wafer 200 may be rotated during the scanning process. In an embodiment employing the wafer 300 of FIG. 3, the optical sensor 430 may be adapted to move linearly along the wafer flat 310 to read the identification notches 330. The scanner 420 may be included in a variety of fabrication equipment, such as a wafer sorter, a process tool, a metrology tool, a material handling device, etc. Generally, the scanner 420 may include a general purpose or special purpose processing unit (e.g., microprocessor or ASIC) operable to execute program instructions for decoding the identification notches 230 read by the sensor 430.

In some instances, a wafer 200, 300 that has been misprocessed may be reclaimed. Because the reclaimed wafer 200, 300 is subjected to a different process flow than the original wafer the first time it was processed, it is assigned a new identity. FIG. 5 is a diagram of a reclaimed wafer 500. For purposes of illustration, the wafer type shown in FIG. 3 is used, however, the same techniques may be applied to the wafer type shown in FIG. 2. On the reclaimed wafer 500, the wafer identification descriptor 520 is appended with a reclamation descriptor 550 scribed using additional identification notches 560. The wafer sorter 420 of FIG. 4 may append the reclamation descriptor 550 to the wafer descriptor 520 to identify the reclaimed wafer 500.

Using edge notches 230, 330 to define wafer identification descriptors 220, 320 as described herein, has numerous advantages. The edge notches 230, 330 are less susceptible to processing related damage that renders other types of identification codes unreadable. Discoloration of the wafer surface does not tend to degrade the wafer identification descriptors 220, 320. The algorithm required to read and decode the identification notches 220, 320 is considerably less complex than the optical techniques employed to read conventional surface scribed identification codes. This reduction in complexity allows scanners to be provided in a wider variety of applications without introducing the configuration control issues present with conventional scanning algorithms, which are frequently modified to attempt to better read the distorted codes.

The particular embodiments disclosed above are illustrative only, as the disclosed subject matter may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the disclosed subject matter. Accordingly, the protection sought herein is as set forth in the claims below.

We claim:

1. An apparatus, comprising:
a semiconductor wafer having a surface terminating in an edge; and
a plurality of notches defined along the edge, the plurality of notches encoding a wafer identification descriptor for the wafer.

2. The apparatus of claim 1, wherein a width of the notches is varied to define the wafer identification descriptor.

3. The apparatus of claim 1, wherein a spacing of the notches is varied to define the wafer identification descriptor.

4. The apparatus of claim 1, wherein a width and a spacing of the notches are varied to define the wafer identification descriptor.

5. The apparatus of claim 1, wherein a subset of the plurality of notches encodes a reclamation descriptor.

6. The apparatus of claim 1, further comprising an orientation notch defined in the wafer proximate the edge.

7. The apparatus of claim 1, wherein the edge defines a wafer flat on the wafer, and the plurality of notches is defined along the wafer flat.

8. A system for identifying wafers, each wafer including a surface terminating in an edge and a plurality of notches defined along the edge, the system comprising a scanner operable to scan at least a portion of a wafer including the plurality of notches and decode the scan of the plurality of notches to generate a wafer identification descriptor for the wafer.

9. The system of claim 8, wherein the scanner comprises an optical sensor.

10. The system of claim 8, wherein the scanner is adapted to identify a reclamation descriptor encoded in the plurality of notches.

11. The system of claim 8, wherein the scanner is operable to decode the wafer identification descriptor based on a width of each of the notches.

12. The system of claim 8, wherein the scanner is operable to decode the wafer identification descriptor based on spacings between the notches.

13. The system of claim 8, wherein the scanner is operable to decode the wafer identification descriptor based on a width of each of the notches and spacings between the notches.

14. A method for identifying a wafer including a surface terminating in an edge and a plurality of notches defined along the edge, comprising:
scanning at least a portion of a wafer including the plurality of notches; and
decoding the scan of the plurality of notches to generate a wafer identification descriptor associated with the wafer.

15. The method of claim 14, further comprising decoding a subset of the plurality of notches to determine a reclamation descriptor associated with the wafer.

16. The method of claim 14, further comprising decoding the wafer identification descriptor based on a width of each of the notches.

17. The method of claim 14, further comprising decoding the wafer identification descriptor based on spacings between the notches.

18. The method of claim 14, further comprising decoding the wafer identification descriptor based on a width of each of the notches and spacings between the notches.
